(19) United States
(12) Patent Application Publication
(10) Pub. No.: US 2026/0129981 A1
(43) Pub. Date: May 7, 2026

(54) IMAGE SENSOR PACKAGES AND RELATED METHODS

(71) Applicant: SEMICONDUCTOR COMPONENTS INDUSTRIES, LLC, Scottsdale, AZ (US)

(72) Inventors: Jorge LUBGUBAN, Danbury, CT (US); Gabrielle ROBERT, Fishkill, NY (US)

(73) Assignee: SEMICONDUCTOR COMPONENTS INDUSTRIES, LLC, Scottsdale, AZ (US)

(21) Appl. No.: 18/936,155

(22) Filed: Nov. 4, 2024

(51) Int. Cl. H01L 27/146

(52) U.S. Cl. CPC H10F 39/011; H10F 39/811

(57) ABSTRACT

Implementations of a method of forming an image sensor package may include providing an image sensor substrate including image sensor die; bonding an optically transmissive substrate to the image sensor substrate; forming a plurality of electrical interconnects on the image sensor substrate; and, after forming the plurality of electrical interconnects, thinning the optically transmissive substrate to a desired thickness.

### BACKGROUND

### 1. Technical Field

Aspects of this document relate generally to image sensor devices and image sensor packages.

### 2. Background

Various semiconductor package designs have been created that assist with forming electrical connections between a semiconductor die and a motherboard or other circuit board to which a semiconductor package is attached. Other semiconductor packages work to protect a semiconductor die from shock or vibration. Yet other semiconductor packages include components that work to prevent damage to the semiconductor die from electrostatic discharge.

### SUMMARY

Implementations of a method of forming an image sensor package may include providing an image sensor substrate including image sensor die; bonding an optically transmissive substrate to the image sensor substrate; forming a plurality of electrical interconnects on the image sensor substrate; and, after forming the plurality of electrical interconnects, thinning the optically transmissive substrate to a desired thickness.

Implementations of a method of forming an image sensor package may include one, all, or any of the following:

The method may include eliminating scratches from an exposed surface of the optically transmissive substrate through the thinning.

Thinning may include grinding.

Thinning may include polishing.

Forming a plurality of interconnects may include coupling a plurality of balls to the image sensor substrate.

The method may include not using a protective tape on an exposed surface of the optically transmissive substrate.

Implementations of a method of forming an image sensor package may include providing an image sensor substrate including image sensor die; bonding an optically transmissive substrate to the image sensor substrate; forming a titanium tungsten layer on a largest planar surface of the optically transmissive substrate; forming a plurality of electrical interconnects on the image sensor substrate; and, after forming the plurality of electrical interconnects, removing the titanium tungsten layer.

Implementations of a method of forming an image sensor package may include one, all, or any of the following:

Forming the titanium tungsten layer may occur before bonding the optically transmissive substrate.

Forming the titanium tungsten layer may occur after bonding the optically transmissive substrate.

The method may include eliminating scratches in the titanium tungsten layer through removing the titanium tungsten layer.

The titanium tungsten layer may be on a largest planar surface of the optically transmissive substrate that faces away from the image sensor substrate.

Forming the plurality of interconnects further may include coupling a plurality of balls to the image sensor substrate.

The method may include not using a protective tape on an exposed surface of the optically transmissive substrate.

Forming the titanium tungsten layer further may include forming the layer across the entire largest planar surface of the optically transmissive substrate.

Forming the plurality of interconnects further may include forming a through silicon via.

Implementations of a method of forming an image sensor package may include providing an image sensor substrate including image sensor die; bonding an optically transmissive substrate to the image sensor substrate; forming a titanium tungsten layer on a portion of a largest planar surface of the optically transmissive substrate; and applying a protective tape over the titanium tungsten layer and the largest planar surface of the optically transmissive substrate. The method may include forming a plurality of electrical interconnects on the image sensor substrate; after forming the plurality of electrical interconnects, removing the protective tape; and removing the titanium tungsten layer.

Implementations of a method of forming an image sensor package may include one, all, or any of the following:

The titanium tungsten layer may be located around a perimeter of the optically transmissive substrate.

The titanium tungsten layer may be located around perimeters of the image sensor die.

The titanium tungsten layer may be located around a perimeter of the optically transmissive substrate.

The method may include eliminating scratches in the optically transmissive substrate through removing the protective tape, and preventing damage to an edge area of the optically transmissive substrate through the titanium tungsten layer.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a side cross sectional view of a portion of an implementation of an image sensor substrate bonded to an implementation of an optically transmissive substrate with an implementation of a protective tape coupled thereto;

FIG. 2 is a cross sectional view of a portion of an implementation of a thick optically transmissive substrate coupled to an implementation of an image sensor substrate;

FIG. 3 is a cross sectional view of the thick optically transmissive substrate of FIG. 2 following formation of an electrical interconnect;

FIG. 4 is a cross sectional view of the thick optically transmissive substrate of FIG. 3 following thinning of the thick optically transmissive substrate to a desired thickness to remove scratches and other defects;

FIG. 5 is a cross sectional view of a portion of an image sensor substrate coupled with a optically transmissive substrate with a protective tape coupled thereto;

FIG. 6 is a cross sectional view of a portion of an image sensor substrate coupled with an optically transmissive substrate with a layer of titanium tungsten formed thereon;

FIG. 7 is a cross sectional view of a portion of an implementation of a image sensor substrate coupled with an implementation of an optically transmissive substrate with a titanium tungsten layer formed over a portion of the optically transmissive substrate and a protective tape coupled thereon;

FIG. 8 is a cross sectional view of a portion of an implementation of an image sensor substrate coupled with an implementation of an optically transmissive substrate with a titanium tungsten layer coupled to the optically transmissive substrate;

FIG. 9 is a cross sectional view of the image sensor substrate of FIG. 8 following formation of a through silicon via therein;

FIG. 10 is a cross sectional view of the image sensor substrate of FIG. 9 following removal of photoresist;

FIG. 11 is a cross sectional view of the image sensor substrate of FIG. 10 following formation of an oxide layer thereon;

FIG. 12 is a cross sectional view of the image sensor substrate of FIG. 11 following etching of the oxide;

FIG. 13 is a cross sectional view of the image sensor substrate of FIG. 12 following sputtering of a copper seed layer thereon;

FIG. 14 is a cross sectional view of the image sensor substrate of FIG. 13 following formation of a thick photoresist layer around the through silicon via;

FIG. 15 is a cross sectional view of the image sensor substrate of FIG. 14 following electroplating of copper;

FIG. 16 is a cross sectional view of the image sensor substrate of FIG. 15 following removal of the thick photoresist layer;

FIG. 17 is a cross sectional view of the image sensor substrate of FIG. 16 following etching of the copper seed layer;

FIG. 18 is a cross sectional view of the image sensor substrate of FIG. 17 following application of a solder mask material over the through silicon via;

FIG. 19 is a cross sectional view of the image sensor substrate of FIG. 18 following formation of an opening in the solder mask material;

FIG. 20 is a cross sectional view of the image sensor substrate of FIG. 19 following formation/placement of a fall in the opening; and

FIG. 21 is a cross sectional view of the image sensor substrate of FIG. 20 following removal of the titanium tungsten layer from the optically transmissive substrate.

### DESCRIPTION

This disclosure, its aspects and implementations, are not limited to the specific components, assembly procedures or method elements disclosed herein. Many additional components, assembly procedures and/or method elements known in the art consistent with the intended methods of forming image sensor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such methods of forming image sensor packages, and implementing components and methods, consistent with the intended operation and methods.

Referring to FIG. 1, an implementation of a portion of an image sensor substrate 2 is illustrated bonded to an optically transmissive substrate 4. The image sensor substrate 2 includes or more or a plurality of image sensor die that have been formed in the semiconductor substrate material of the image sensor substrate. The image sensor substrate may be formed of a wide variety of semiconductor substrate types, including, by non-limiting example, silicon, silicon on insulation, silicon carbide, gallium arsenide, gallium nitride, sapphire, or ruby. The image sensor die may be front side illuminated or back side illuminated in various implementations. The image sensor die may include various structures that form various devices like pixels designed to detect/respond to electromagnetic radiation in a wide variety of wavelengths including, by non-limiting example, visible light, infrared light, ultraviolet light, x-rays, gamma rays, radio waves, cosmic rays, or any other desired wavelength of electromagnetic radiation. The various image sensor package implementations and methods of forming the same disclosed herein may be employed with a wide variety of image sensor die types and in a wide variety of image sensor package types including stacked die and bonded die packages.

In FIG. 1, a protective tape 6 has been applied over the exposed largest planar surface 8 of the optically transmissive substrate 4 to prevent damage to the exposed largest planar surface 8. During processing, various scratches due to physical handling/contacting with the exposed largest planar surface 8 can occur which leaves permanent marks on the surface which can cause light scattering and result in various image defects. Also, the various chemicals used when processing the bonded optically transmissive substrate 4 and image sensor substrate 2 may etch or otherwise degrade the finish on the exposed largest planar surface, causing defects in the resulting images. Because of this, the use of protective tape 6 allows any mechanical scratching to be received by the surface of the tape instead of the exposed larges planar surface. Because various implementations of the protective tape 6 are resistant to various processing chemicals and high processing temperature, the protective tape also helps prevents exposure of the exposed largest planar surface 8 to the chemicals and resulting damage therefrom.

However, it has been noted that the protective tape 6 is prone to fail in protecting the region around edge of the wafer, as the protective tape 6 tends to separate in this area allowing chemicals to enter in and damage areas of the exposed largest planar surface 8. The protective tape 6 is also expensive due to the chemical and temperature requirements along with the need to be able to separate it from the optically transmissive substrate 4 when processing is completed. Because of this, the inability of the protective tape 6 to fully protect the edge region can cause yield loss for image sensor packages located around the edge of the optically transmissive substrate even after it has been applied.

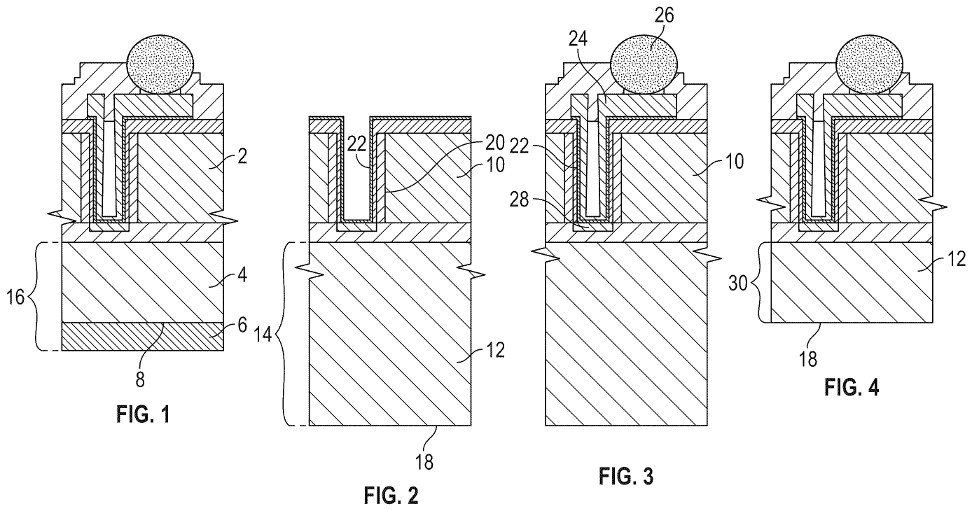

Referring to FIG. 2, another implementation of an image sensor substrate 10 after bonding to an optically transmissive substrate 12 is illustrated. Note that in this figure, a thickness 14 of the optically transmissive substrate 12 is thicker than the thickness 16 of the optically transmissive substrate 16 in FIG. 1. Though neither of these drawings is to scale, the observed difference in thickness between the two figures is intentional and used to show that the thickness 14 of the optically transmissive substrate 12 is thicker than the finished thickness 16 of the optically transmissive substrate 16. The use of a thicker optically transmissive substrate provides several benefits during processing. Because of the greater thickness, any scratches that are made on the exposed largest planar surface 18 remain there and can be entirely removed by thinning the optically transmissive substrate 12 to the finished thickness 16. Likewise damage to the exposed largest planar surface 18 due to chemical or other processing exposure can also be entirely removed through thinning.

In FIG. 2, the image sensor substrate 10 is illustrated following formation of a through silicon/through substrate via 20 therein and application of a copper seed layer 22 into the via. Since the optically transmissive substrate 16 is thicker than the finished thickness, any damage to the exposed largest planar surface 18 during these operations can be removed later by thinning the substrate. FIG. 3 illustrates the image sensor substrate 10 following electroplating of a copper layer 24 onto the copper seed layer 22 and after attaching ball 26 to the copper layer 24 to form an electrical interconnect with a pad 28 in the image sensor substrate 10. As this process can be repeated numerous times across the image sensor substrate 10, a plurality of electrical interconnects can thus be formed.

Referring to FIG. 4, the image sensor substrate 10 is illustrated following thinning of the optically transmissive substrate 12 to finished thickness 30. In the process any scratches or other damage induced during the processing to form the electrical interconnects is removed. In particular implementations, the thinning process involves grinding. In other implementations, in addition to grinding, polishing may be employed to create a desired surface finish in the exposed largest planar surface 18. In this way, no protective tape was used, but the finish and integrity of the exposed largest planar surface 18 is retained.

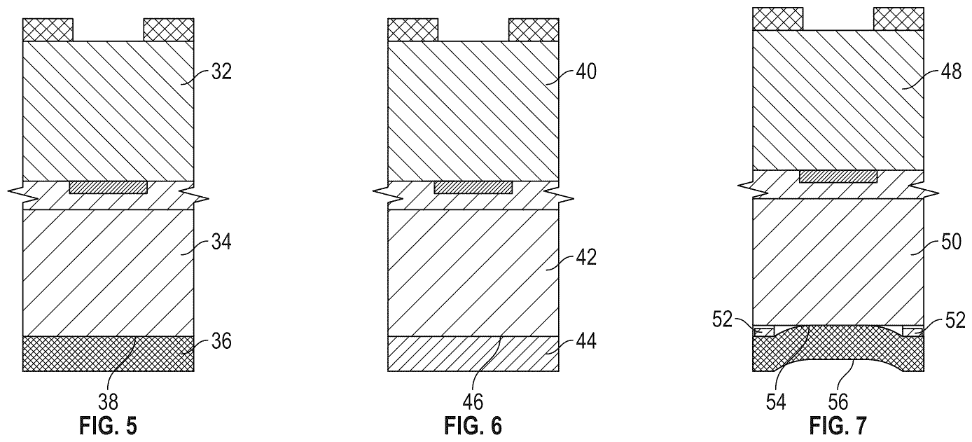

Other method implementations disclosed in this document employ optically transmissive substrates that remain at a finished thickness, but use other techniques to protect the exposed largest planar surface of the substrates. Referring to FIG. 5, an implementation of an image sensor substrate 32 is illustrated following bonding to an optically transmissive substrate 34. In this implementation, a protective tape 36 has been bonded to the exposed largest planar surface 38 of the optically transmissive substrate 34. Because only a protective tape 36 is being used in this implementation, the issues with higher cost and inability to fully protect the edge areas of the optically transmissive substrate 34 are both present.

Referring to FIG. 6, another implementation of an image sensor substrate 40 bonded to an optically transmissive substrate 42 is illustrated. In this implementation, a titanium tungsten layer 44 has been formed over the exposed largest planar surface 46 of the optically transmissive substrate 42. The titanium tungsten layer 44 has several effects and offers various process options. First, the titanium tungsten layer 44 now, instead of the exposed largest planar surface, will receive scratches and any processing damage during further processing of the bonded image sensor substrate 40 and optically transmissive substrate 42 and can then be removed using wet etching at the end of the process flow, to expose the protected largest planar surface 46. Secondly, the deposition/formation conditions for the titanium tungsten layer 44 can be adjusted to make the resulting layer/film apply tensile to compressive stress to the optically transmissive substrate 42. For example, where the titanium tungsten layer 44 is deposited using sputtering, the power used and pressure in the sputtering chamber can be used to adjust the stress of the film from a compressive stress of about 1 gigapascal to a tensile stress of about 500 megapascals. Because of this, in various method implementations, if adjustment of the bow or warpage of the image sensor substrate 40 and/or optically transmissive substrate 42 is desired, the compressive/tensile stress of the titanium tungsten layer can be correspondingly tuned to place the image sensor substrate 40/optically transmissive substrate 42 in a desired bow/warpage/flatness for subsequent processing steps.

Also, the use of the titanium tungsten film permits process tools that employ electrostatic chucking to readily handle the bonded image sensor substrate 40 and optically transmissive substrate 42 without needing upgrades to deal with the increased dielectric properties introduced by the optically transmissive substrate 42. Furthermore, because the titanium tungsten layer 44 is fully or substantially opaque to visible light, the various processing tools will be able to see the optically transmissive substrate during processing operations.

In various method implementations, the application of the titanium tungsten layer 44 occurs prior to the bonding of the image sensor substrate 40 and the optically transmissive substrate 42. In other method implementations, the application/formation of the titanium tungsten layer 44 may occur after bonding of the image sensor substrate 40 and the optically transmissive substrate 42. The timing of the formation of the titanium tungsten layer 44 may depend in part on whether the warpage of the optically transmissive substrate 42 may need to be adjusted or the warpage of the combined image sensor substrate 40/optically transmissive substrate 42 needs to be adjusted.

Because the titanium tungsten layer 44 is removable using wet etching after processing after bonding is completed, all of the scratches and surface defects are removed without the use of a protective tape. In this method implementation, the titanium tungsten layer 44 has been deposited over the entire exposed largest planar surface 46 of the optically transmissive substrate 42. In other method implementations, however, forming the titanium tungsten layer may occur over less than the entire exposed largest planar surface. In various implementations the titanium tungsten layer may be between about 500 angstroms to about 20,000 angstroms thick.

Referring to FIG. 7, an implementation of an image sensor substrate 48 is illustrated following bonding to optically transmissive substrate 50. A titanium tungsten layer 52 has been formed around the edge of the exposed largest planar surface 54 of the optically transmissive substrate 50. In some implementations, this edge corresponds with the outer edge of the image sensor substrate 48 such as, by non-limiting example, in an edge exclusion region of a wafer. In other implementations, the edge may extend further toward a center point/region of the optically transmissive substrate 50 and cover less than half or more than half of the exposed largest planar surface 54. In other implementations, the titanium tungsten layer 52 may take the form of a grid of intersecting lines that are aligned with the die streets or edges of the various image sensor die included in the image sensor substrate 48. In yet other implementations, the titanium tungsten layer 52 may take the form of a set of discrete rectangular shapes that do not contact one another aligned with a perimeter of all or a portion of several or all of the image sensor die. In other implementations, the titanium tungsten layer 52 may take the form of parallel or substantially parallel lines aligned with the X or Y die streets of the array of image sensor die included in the image sensor substrate 48. In yet other implementations, the shape of the titanium tungsten layer 52 may take the shape of various closed shapes and form a pattern that does or does not correspond with the pattern of the image sensor die. For example, the titanium tungsten layer 52 may take the form of a pattern of open circles that are each arranged over a center or center region of each image sensor die. In another implementation, however, the titanium tungsten layer 52 may take the form of a pattern of closed circles that form a grid that does not correspond with the grid pattern of the image sensor die. A wide variety of various shapes for the titanium tungsten layer may be constructed using the principles disclosed herein.

In particular implementations, the titanium tungsten layer 52 is located around a perimeter of the optically transmissive substrate 50 that corresponds with an edge exclusion region of the image sensor substrate 48. In this implementation, the width of the titanium tungsten layer 52 is set so that when the bonded optically transmissive substrate 50 is placed in various substrate handling equipment like an aligner, the opaque titanium tungsten layer 52 permits the aligner to see the substrate and perform the alignment operation.

In all of the foregoing implementations with various arrangements and forms of the titanium tungsten layer 52, protection against scratches and processing damage for the exposed largest planar surface 54 of the optically transmissive substrate 50 is accomplished using protective tape 56. The protective tape 56 is coupled over the titanium tungsten layer 52 and the exposed largest planar surface 54 and, since the tape is flexible, allows for conformal coverage of the surface. Where the titanium tungsten layer 52 is located around the perimeter of the optically transmissive substrate 50 (either alone or in combination with any of the previously mentioned layer configurations), it helps prevent processing damage caused by delamination of the protective tape 56 during processing as previously described due to the resistance of the titanium tungsten layer.

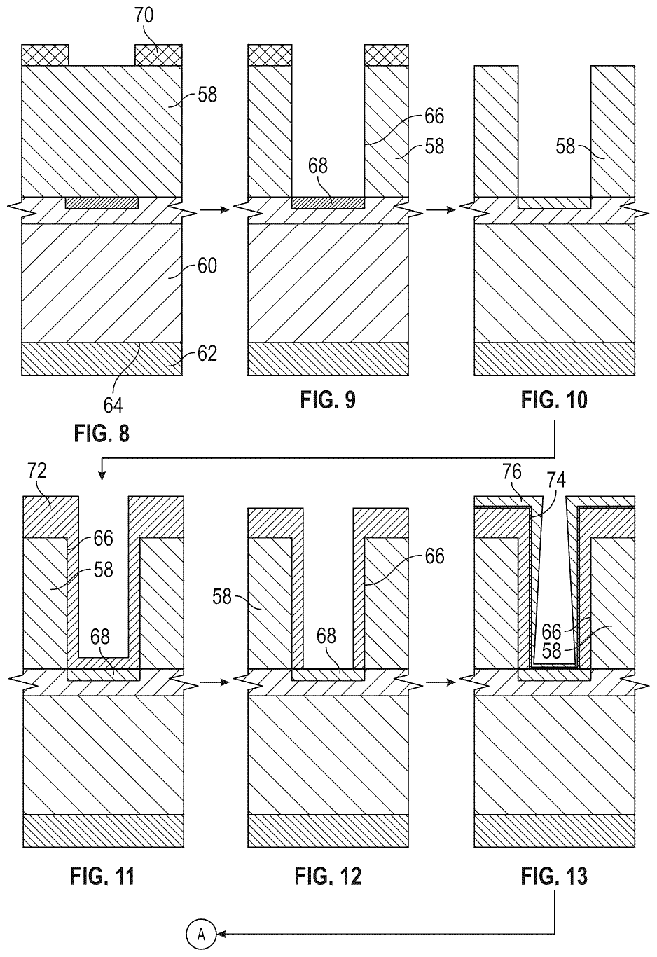

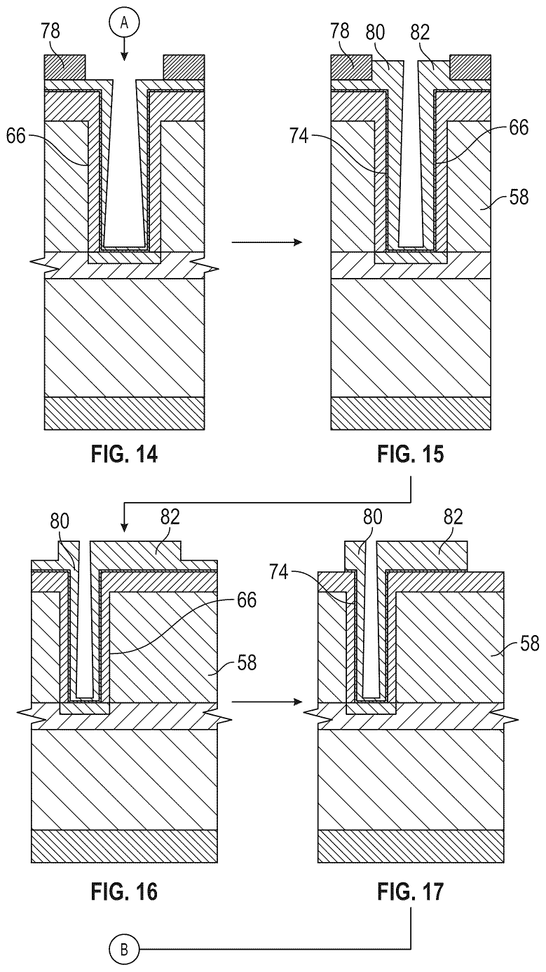

The previously described implementations that employ titanium tungsten layer configurations may be utilized in various methods of forming an image sensor package that includes electrical interconnects. Referring to FIG. 8, an implementation of an image sensor substrate 58 after bonding to an optically transmissive substrate 60 is illustrated. The bonding process may take place using a wide variety of techniques in various package implementations that create gapped or gapless image sensor packages including, by non-limiting example, use of a dam and adhesive, use of an adhesive as a dam, hybrid bonding, oxide bonding, adhesive bonding, or any other system or method compatible with bonding the materials of the particular optically transmissive substrate 60 to the particular image sensor substrate 58. As illustrated, a titanium tungsten layer 62 has been formed over the exposed largest planar surface 64 of the optically transmissive substrate 60, either prior to the bonding operation or after the bonding operation. The titanium tungsten layer 62 may cover the exposed largest planar surface 64 in a blanket layer or a patterned layer like any previously disclosed in this document in various method implementations. While the method implementation disclosed in FIGS. 8-21 shows just the titanium tungsten layer 62, where a patterned layer is employed, a protective tape like those disclosed previously would be applied over the titanium tungsten layer 62 as disclosed in this document and the processing operations would then proceed as described herein. Also illustrated in FIG. 8 is a patterned layer 70 that has been formed of a photoresist or other photodefinable material that leaves an opening for etching.

Referring to FIG. 9, the image sensor substrate 58 is illustrated following formation of a through silicon via (through substrate via) 66 through the thickness of the silicon material of the substrate to a pad 68 on the image sensor substrate 58. The through substrate via 66 here has been formed using a deep reactive ion etching process using the pad 68 as an etch stop. Referring to FIG. 10, the image sensor substrate 58 is illustrated following removing of the patterned layer 70 using an ashing, solvent stripping, or other process consistent with the material of the patterned layer 70.

FIG. 11 illustrates the image sensor substrate 58 following formation of a silicon dioxide layer 72 over the through silicon via 66 and upper surface of the substrate. The silicon dioxide layer 72 may be formed in various method implementations using a chemical vapor deposition process which also deposits the silicon dioxide over the surface of the pad 68. To remove the electrically insulative material from the surface of the pad 68, a reactive ion etching process is used to directionally etch the silicon dioxide from the surface of the pad while leaving it on the sidewalls of the through silicon via, as the illustration of the image sensor substrate 58 of FIG. 12 shows.

A seed layer of copper is then formed over the silicon dioxide layer 72. Referring to FIG. 13, in a particular implementation, the seed layer is formed by depositing a layer of titanium 74 using a sputtering process followed by depositing a seed layer of copper 76 using a sputtering process. Because of the high aspect ratio of the through silicon via 66, the thickness of the seed layer of copper is thicker at the top of the via than at the bottom. Now that a layer of copper is present over the entire upper surface of the image sensor substrate 58, the substrate is ready for an electroplating operation.

Referring to FIG. 4, a patterned thick photoresist layer 78 is illustrated following formation around the through silicon via 66 prior to electroplating. This thick photoresist layer may be several microns thick to tens of microns thick depending on the desired thickness of the electroplated layer. FIG. 15 illustrates the image sensor substrate 58 following the electroplating of a copper layer 80 over the seed layers and up above the upper surface of the through silicon via 66 to form a pad 82. FIG. 16 illustrates the image sensor substrate 58 following removal of the thick photoresist layer 78 using any process disclosed in this document consistent with the removal of the photoresist material. As illustrated in this broader view, the pad 82 extends a distance to the side of the through silicon via 66 to form part of the eventual electrical interconnect. Also illustrated in FIGS. 15 and 16 is that the copper layer 80 does not fully fill the through silicon via 66 in this implementation. However, in other implementations, the copper layer 80 may fully or substantially (except for a small seam in the center) fill the through silicon via 66.

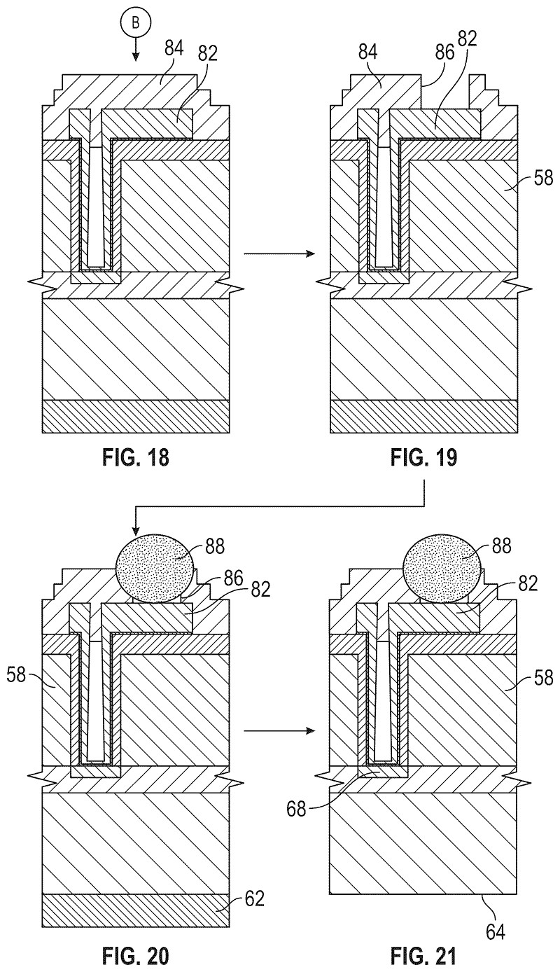

Referring to FIG. 17, the image sensor substrate 58 is illustrated following etching of the thinner portions of the copper layer 80 and the titanium layer 74 on the upper surface of the substrate to provide for electrical isolation between the various through silicon vias being formed. This process forms the final surface of the pad 82. The etching processes used here may be any consistent with the materials including wet etching, dry etching, or any combination thereof. FIG. 18 illustrates the image sensor substrate 58 after application of a solder mask layer 84 over the pad 82 which forms a substantially conformal layer at a desired thickness. In this implementation, the solder mask layer 84 is photo definable, and so after exposure to light and a development process, a portion of the solder mask layer 84 over the pad 82 has been removed creating a pad opening 86, as illustrated in FIG. 19. Since the material of the solder mask layer 84 is not electrically conductive, this layer helps passivate/electrically isolate the upper surface of the image sensor substrate 58.

Referring to FIG. 20, the image sensor substrate 58 is illustrated following formation/dropping of ball 88 into pad opening 86 and contacting with the material of pad 82. In various method implementations, a wide variety of balls may be utilized including, by non-limiting example, copper balls, solder balls, silver balls, aluminum balls, copper alloy balls, silver alloy balls, aluminum alloy balls, or any combination thereof. In some implementations, various underbump metals may first be deposited prior to formation/dropping of the ball 88 in the pad opening 86 to assist with adhesion with the material of the pad 82 and/or prevent ball cracking during later processing/operation. Ball 88 in the illustrated implementation is a solder ball, and so after being dropped into the pad opening 86, is heated in a reflow operation to form a metallic bond with the material of the pad 82 forming the structure illustrated in FIG. 21. Here an electrical interconnect from the pad 68 to the ball 88 has been formed. Also illustrated here is that the titanium tungsten layer 62 illustrated in FIG. 20 has been removed using a wet etching process to leave the exposed largest planar surface 64 of the optically transmissive substrate 60 fully exposed and free from scratches or other processing damage without the use of a protective tape. However, in implementations where a protective tape was still used, due to the shape of the titanium tungsten layer, the protective tape would be removed prior to the wet etching removal of the titanium tungsten layer. At this point the image sensor substrate 58 is now prepared for further processing operations, including singulation operations that separate the various image sensor die into image sensor packages.

The foregoing process of using the titanium tungsten layer to protect the exposed surface of the optically transmissive substrate during processing is merely for the exemplary purposes of this disclosure. A wide variety of other method implementations are possible using the principles disclosed herein.

In places where the description above refers to particular implementations of methods of forming image sensor packages and implementing components, sub-components, methods and sub-methods, it should be readily apparent that a number of modifications may be made without departing from the spirit thereof and that these implementations, implementing components, sub-components, methods and sub-methods may be applied to other methods of forming image sensor packages.

What is claimed is:

1. A method of forming an image sensor package, the method comprising:
providing an image sensor substrate comprising image sensor die;
bonding an optically transmissive substrate to the image sensor substrate;
forming a plurality of electrical interconnects on the image sensor substrate; and
after forming the plurality of electrical interconnects, thinning the optically transmissive substrate to a desired thickness.

2. The method of claim 1, further comprising eliminating scratches from an exposed surface of the optically transmissive substrate through the thinning.

3. The method of claim 1, wherein thinning comprises grinding.

4. The method of claim 3, wherein thinning comprises polishing.

5. The method of claim 1, wherein forming a plurality of interconnects further comprises coupling a plurality of balls to the image sensor substrate.

6. The method of claim 1, further comprising not using a protective tape on an exposed surface of the optically transmissive substrate.

7. A method of forming an image sensor package, the method comprising:
providing an image sensor substrate comprising image sensor die;
bonding an optically transmissive substrate to the image sensor substrate;
forming a titanium tungsten layer on a largest planar surface of the optically transmissive substrate;
forming a plurality of electrical interconnects on the image sensor substrate; and
after forming the plurality of electrical interconnects, removing the titanium tungsten layer.

8. The method of claim 7, wherein forming the titanium tungsten layer occurs before bonding the optically transmissive substrate.

9. The method of claim 7, wherein forming the titanium tungsten layer occurs after bonding the optically transmissive substrate.

10. The method of claim 7, further comprising eliminating scratches in the titanium tungsten layer through removing the titanium tungsten layer.

11. The method of claim 7, wherein the titanium tungsten layer is on a largest planar surface of the optically transmissive substrate that faces away from the image sensor substrate.

12. The method of claim 7, wherein forming the plurality of interconnects further comprises coupling a plurality of balls to the image sensor substrate.

13. The method of claim 7, further comprising not using a protective tape on an exposed surface of the optically transmissive substrate.

14. The method of claim 7, wherein forming the titanium tungsten layer further comprises forming across the entire largest planar surface of the optically transmissive substrate.

15. The method of claim 7, wherein forming the plurality of interconnects further comprises forming a through silicon via.

16. A method of forming an image sensor package, the method comprising:
providing an image sensor substrate comprising image sensor die;
bonding an optically transmissive substrate to the image sensor substrate;
forming a titanium tungsten layer on a portion of a largest planar surface of the optically transmissive substrate;
applying a protective tape over the titanium tungsten layer and the largest planar surface of the optically transmissive substrate;
forming a plurality of electrical interconnects on the image sensor substrate;
after forming the plurality of electrical interconnects, removing the protective tape; and
removing the titanium tungsten layer.

17. The method of claim 16, wherein the titanium tungsten layer is located around a perimeter of the optically transmissive substrate.

18. The method of claim 16, wherein the titanium tungsten layer is located around perimeters of the image sensor die.

19. The method of claim 17, wherein the titanium tungsten layer is located around a perimeter of the optically transmissive substrate.

20. The method of claim 16, further comprising:
eliminating scratches in the optically transmissive substrate through removing the protective tape; and
preventing damage to an edge area of the optically transmissive substrate through the titanium tungsten layer.
